(19) United States
(12) Patent Application Publication
(10) Pub. No.: US 2001/0045610 A1
(43) Pub. Date: Nov. 29, 2001

(54) MICRO-MACHINED SURFACE STRUCTURE

(76) Inventor: HIROSHI TOUGE, Aichi-ken (JP)

Correspondence Address: SUGHRUE MION ZINN MACPEAK & SEAS PLLC, 2100 PENNSYLVANIA AVENUE NW, WASHINGTON, DC, 20037-3213, US

(21) Appl. No.: 09/471,273

(22) Filed: Dec. 23, 1999

(30) Foreign Application Priority Data
Dec. 24, 1998 (JP) 10-365799

(51) Int. Cl. H01L 29/82

(52) U.S. Cl. 257/415

(57) ABSTRACT

The micro-machined surface structure includes a substrate 1, a circuit 10 comprising an n-layer or a p-layer diffused after ion implantation of impurities onto the substrate, an oxide film 5 for protecting the circuit 10 and a nitride film 6 formed on the oxide film. A circuit connection portion 11 is electrically connected with the circuit 10 and a structural body comprising polysilicon is formed on the circuit connection portion 11 and on the nitride film 6 in which the nitride film is formed between the oxide film 5 and the circuit connection portion 11 on the substrate.

### BACKGROUND OF THE INVENTION

1. Field of the Invention

The present invention is directed to a micro-machined surface structure and in particular relates to the structure of a micro-machined surface having a structural body prepared by separating a movable portion and a fixed portion by surface micro-machining and removing a sacrificial layer by etching between a substrate and a layer comprising polysilicon.

2. Related Art Statement

A micro-machined surface comprises a circuit including an n-layer or p-layer formed by diffusion after implantation of impurities on a substrate, an oxide film formed on the circuit for protecting the circuit, a nitride film formed on the oxide film and circuit connection portions electrically connected with the circuit and, further, a structural body comprising polysilicon (poly-Si), connected to an anchor portion or a substrate circuit and formed on the circuit connection portion and the nitride film as a fixed electrode or the anchor portion has been known and a sensor of such a structure is disclosed, for example, in U.S. Pat. No. 5,662,771.

A micro-machined surface structure shown in the prior art literature (see FIG. 13) has a construction in which an N⁺ electrode is formed on a substrate, an oxide film, a poly-Si film, an SiN film and a sacrificial layer are disposed thereon and further, a poly-Si layer as a structural body is formed thereon. The structural body comprising poly-Si is connected electrically from the N⁺ wiring by way of a circuit connection port with the lower circuit. Usually, in the micro-machined surface of the structure described above, the thickness of the poly-Si film as the upper structural body is about 2 μm.

In the structural body having a film thickness of about 2 μm as described above, for forming a movable portion (the right upper poly-Si layer in FIG. 3) separated from a fixed portion and contiguous with the circuit, a fixed electrode and an anchor portion are separated from the movable portion, an etching solution is introduced from the separated portion to the inside of the structural body formed with the sacrificial layer, and the sacrificial layer between the poly-Si and the nitride film is removed by etching.

In the case of preparing a sensor having the movable portion, by the method described above (an acceleration sensor, an angular velocity sensor or the like), in particular a sensor comprising polysilicon in which the movable portion has a film thickness of about 10 μm, no undesired effects are caused by etching when the width of the circuit connection portion is made somewhat larger. However, when the width of the circuit connection portion is reduced along with a size reduction of the substrate and the structural body is separated at a position spaced apart by several pin (about 2-3 μm) from the circuit connection portion, the following problems are caused in the course of separating the structural body by dry etching of poly-Si and subsequently releasing the sacrificial layer by etching. That is, when the movable portion is formed on an optional shape by dry etching or the like when the thickness of an upper poly-Si film that forms the structural body is increased to about 10 μm, etching time is adjusted and differs greatly in view of the focal depth. Further, when etching treating is conducted by high density plasmas for promoting etching treatment, an etching gas or an etching solution penetrates with a lapse of time in the direction of the thickness of the substrate to remove the poly-Si film. However, the etching gas or the etching solution penetrates along the surface of the sacrificial layer as far as the lower substrate to overetch the poly-Si film of the circuit connection portion.

That is, a silicon nitride film is formed below the sacrificial layer with the aim of protecting the lower circuit but, since the circuit connection portion also comprises the same film made of poly-Si as that of the structural body, etching gas or etching solution penetrates along the cross sections of the silicon nitride film under the sacrificial layer, the poly-Si film and, further, the oxide film therebelow, it undergoes etching to narrow the width of the circuit connection portion. Therefore, a gap is formed by overetching at the boundary with the poly-Si film in the circuit connection portion.

Therefore, when the sacrificial layer is released by wet etching in the final stage, an etching gas or etching solution intrudes into the gap formed by dry etching in the final stage (gap between the circuit connection portion, and the sacrificial layer, poly-Si and oxide film), and the oxide film formed under the silicon nitride layer for suppressing leakage between the N⁺ circuit layer formed on the lower substrate and the p-type substrate is removed by etching with the etching solution intruding through the gap. As a result, the oxide film protecting leakage between the n-layer and the p-layer occurring on the surface of the substrate is eliminated to cause current leakage on the surface of the substrate thereby deteriorating the performance of the sensor.

Accordingly, the present invention has been accomplished in view of the foregoing problems and it is an object thereof to prevent degradation of the performance due to leakage on the surface of a substrate.

### SUMMARY OF THE INVENTION

The technical feature adopted for solving the subject described above provides a micro-machined surface structure including a substrate, a circuit comprising an n-layer or a p-layer formed by diffusion by ion implantation of impurities on the substrate, an oxide film for protecting the circuit, a nitride film formed on the oxide film, a circuit connection portion electrically connected with the circuit, and a structural body comprising polysilicon and formed on the circuit connection portion and on the nitride film, in which a nitride film is formed between the oxide film and the circuit connection portion on the substrate.

With the construction as described above, since the nitride film is formed between the oxide film and the circuit connection portion and when the structural body is separated near the circuit connection portion, even if poly-Si is overetched, intruding etching solution does not easily reach the oxide film as before, and the film can be protected reliably by the nitride film. Accordingly, the sacrificial layer can be reliably protected from etching also upon releasing by the nitride film formed between the oxide film and the circuit connection portion.

In this case, since leakage current between the circuit of the n-layer and the player substrate can be suppressed by the nitride film, the yield and S/N ratio of the sensor can be improved to prevent degradation in the performance. Further, when such a construction is applied, for example, to an acceleration sensor or an angular velocity sensor, the size for the anchor portion or the fixed electrode electrically connected with the circuit disposed on the substrate can be reduced and the number of electrodes within a unit area can be increased, thereby enabling a reduction in the size of the sensor.

### DESCRIPTION OF THE DRAWINGS

FIG. 1 is a partial sectional view showing the micro-machined surface structure according to one embodiment of the invention;

FIG. 2 shows a production step (step 1) for a micro-machined surface in said one embodiment according to the invention;

FIG. 3 shows a production step (step 2) for a micro-machined surface in said one embodiment according to the invention;

FIG. 4 shows a production step (step 3) for a micro-machined surface in said one embodiment according to the invention;

FIG. 5 shows a production step (step 4) for a micro-machined surface in said one embodiment according to the invention;

FIG. 6 shows a production step (step 5) for a micro-machined surface in said one embodiment according to the invention;

FIG. 7 shows a production step (step 6) for a micro-machined surface in said one embodiment according to the invention;

FIG. 8 shows a production step (step 7) for a micro-machined surface in said one embodiment according to the invention;

FIG. 9 shows a production step (step 8) for a micro-machined surface in said one embodiment according to the invention;

FIG. 10 shows a production step (step 9) for a micro-machined surface in said one embodiment according to the invention;

FIG. 11 shows a production step (step 10) for a micro-machined surface in said one embodiment according to the invention;

FIG. 12 is a plan view of showing the application of the structure of the invention to an angular velocity sensor; and

FIG. 13 is a view showing the structure of a prior art.

### DESCRIPTION OF PREFERRED EMBODIMENTS

The invention is to be explained by way of preferred embodiments with reference to the drawings.

FIG. 1 is an explanatory view for explaining the structure of a micro-machined surface according to the invention in which a lower circuit or an electrode 10 of an n⁺-layer is formed on a p-type silicon substrate (Si substrate) I by ion implantation of impurities such as arsenic and diffusing them by heating. Further, an oxide film 5 is formed on the n⁺-layer and the p-layer of the substrate 1 so as to cover the p-layer and the n⁺-layer for preventing surface leakage on the substrate upon driving of a sensor, and a nitride film 6 to form an etching stopper is formed on the oxide film 5. The nitride film 6 covers the surface and the lateral side in the direction of the film thickness of the oxide film and is formed so as to be in contact with the n⁺-layer for preventing the leakage on the surface of the substrate.

Further, a sacrificial layer 7 is formed on the nitride film 6, and a film for a structural body 8 comprising poly-Si is formed on the sacrificial layer 7. In this embodiment, the electrode 10 is connected electrically by way of the circuit connection portion 11 with a portion that forms an anchor portion or a fixed electrode of the structural body 8, in which the structural body is separated by etching into a fixed portion as an anchor portion or a fixed electrode and a movable portion that moves upon exertion of an external force.

In the construction shown in FIG. 1, the oxide film 5 is formed as a protection film for suppressing the surface leakage of the n⁺-layer and the p-layer on the substrate, and the nitride film 6 is formed so as to cover the oxide film 5 for protecting the oxide film. This is different from the existent construction in that the nitride film 6 completely covers the oxide film 5 from above. In this case, since a portion in direct contact with the n⁺-layer is present, even in a case of deeply etching polysilicon at a thickness of about 10 μm, a connection portion between the nitride film 6 and the n⁺-layer firmly remains even when the lateral side of the circuit connection portion 11 is removed by over-etching as far as the n⁺-layer as shown in FIG. 1. Therefore, the etching solution does not etch the oxide film 5 as the protection film upon etching of the sacrificial layer, so that surface leakage on the substrate can be prevented.

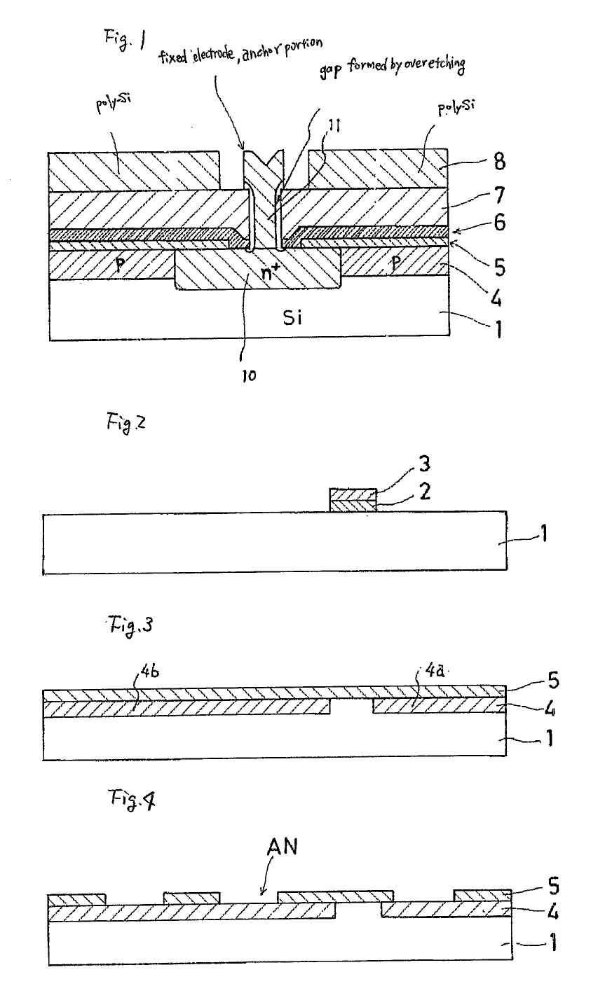

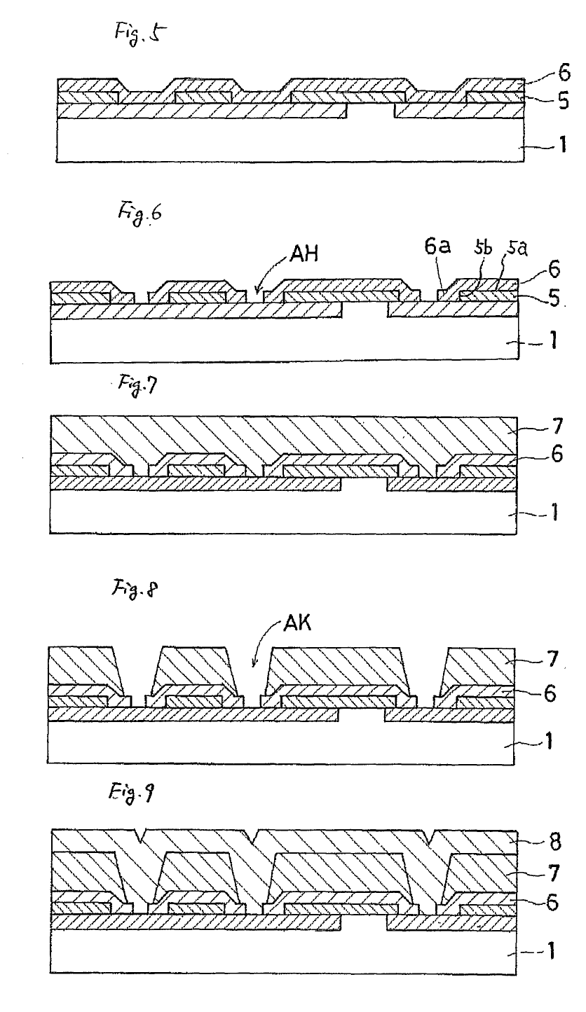

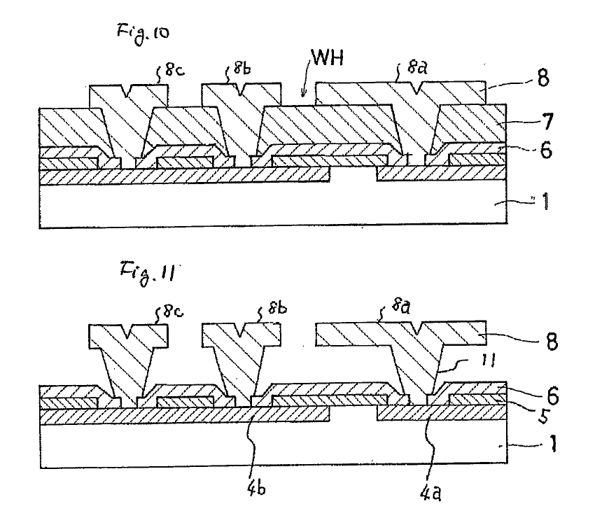

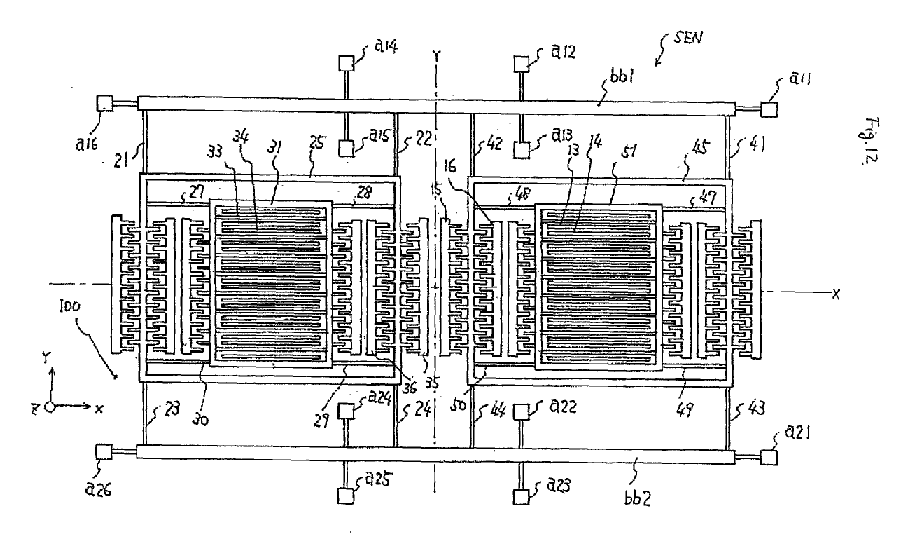

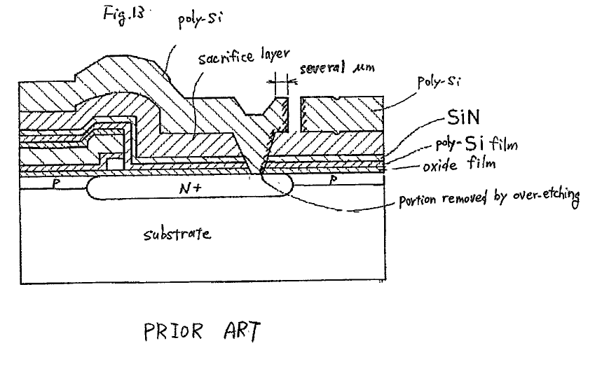

The production method is explained with reference to FIG. 2 through FIG. 11. At first, an oxide film 2 is formed by thermal oxidation on a p-type substrate 1 comprising a silicon wafer and a resist 3 is formed at an area for separating an electrode. Subsequently, when dry etching is applied with a fluoric acid type gas (such as CHF₃), an electrode separation portion on the substrate is left (where the oxide film 2 and the resist 3 are formed, as shown in FIG. 2). Subsequently, the resist 3 formed on the oxide film is peeled and ions such as arsenic ions are implanted to the surface of the substrate while applying a temperature at about 900° C. to the substrate 1. In this case, when a temperature of almost 900° is applied, arsenic ions fuse downward in the substrate 1 to form an n-type diffusion layer as a lower electrode, and an oxide film 5 is formed under the effect of heat on the electrode 4a and 4b as shown in FIG. 3). In this case, if it is intended to form electrodes 4a and 4b with a p-layer relative to the n-type substrate, the p-layer electrode can be formed by implantation of ions such as boron instead of arsenic.

A resist is formed at an area of the oxide film 5 except for a circuit connection portion AN in communication with the lower circuit, the oxide film 5 is separated by dry etching, and when the resist is peeled, the oxide film 5 is separated as shown in FIG. 4). Subsequently, a nitride film 6 is formed entirely over the surface from above by an LPCVD method (Low Pressure CVD Method) as shown in FIG. 5. A resist is then formed at an area other than the circuit connection portion AH in communication with the electrodes 4a and 4b below, the nitride film 6 at the circuit connection portion AH with the lower circuit is removed by dry etching and the resist is peeled, as shown in FIG. 6. In this case, for completely covering the surface 5a and the lateral end 5b of the oxide film 5 with the nitride film 6, an overlap 6a is formed so as to cover the end 5b and it is formed in close contact with no gap on the electrode 4.

Subsequently, a sacrificial layer 7 is formed entirely using phosphorus silicate glass by a CVD method, as shown in FIG. 7. In this case, the etching rate can be increased by incorporation of phosphorus. After forming the sacrificial layer 7, a resist is formed on the sacrificial layer 7 at an area other than the circuit connection portion AK in connection with 4a and 4b, and an aperture is formed by dry etching for the circuit connection portion AK to form an anchor portion or a fixed electrode. The dry etching may be conducted with or without forming a tapered face in the direction of the film thickness. Further, etching is conducted for the circuit connection portion AK for a period of time to remove the sacrificial layer 7 as far as the surface of the substrate, in which the oxide film 5 is protected by the nitride film 6.

Subsequently, after forming a poly-Si film entirely by atmospheric epitaxy as shown in FIG. 9, a resist is formed at an area to be left as a movable portion (vibration portion in the case of conducting vibrations such as in an angular velocity sensor) 8a, and fixed portions (fixed electrode or an anchor portion) 8b and 8c, and a structural body 8 comprising poly-Si is fabricated by dry etching using, for example, CF₄O₂, as shown in FIG. 10). Then, the resist is peeled, wet etching is conducted using buffered hydrofluoric acid from a position WH at which the movable portion 8a and the fixed portions 8b and 8c are separated, and the structural body is released by removing the sacrificial layer 7 by wet etching, to complete a sensor.

In this embodiment, since the nitride film 6 is formed between the oxide film 5 and the circuit connection portion 11, even when the structural body 8 is separated into the movable portion 8a and the fixed portions 8b and 8c near the circuit connection portion, sticking of poly-Si by overetching can be prevented, so that intrusion of an etching solution through the portion WH at which the structural body 8 is separated can be prevented reliably by the nitride film 6 formed with the overlap 6a. Further, also upon releasing, the sacrificial layer 7 can be protected reliably against etching by the nitride film 6 formed between the oxide film 5 and the circuit connection portion 11.

As an example, when the thickness of the substrate is 500 μm, each of the layers is formed to a thickness of 0.5 to 1 μm for the electrode or the circuit 4 formed by diffusion, 0.5 μm for the oxide film 5, 0.5 to 1 μm for the nitride film 6, 3 to 4 μm for the sacrificial layer 7 and 10 μm or more for the structural body 8 comprising poly-Si on the sacrificial layer 7, and to a width of 2 to 3 μm for the circuit connection portion 11 and to about 5 μm for the structural body on the circuit connection portion. WH can be disposed at an optional position for flowing an etching solution upon releasing and, irrespective of the position of WH, leakage current between the n⁺-wiring and p-type substrate can be reduced by the nitride film 6 formed between the oxide film 5 and the circuit connection portion 11, to improve the S/N ratio and enhance the performance. For the releasing, explanation has been made to the case of using an etching solution but an etching gas may also be used.

FIG. 12 shows an angular velocity sensor SEN having the foregoing structure. Referring simply to the sensor SEN. a pair of connection beams bb1 and bb2 extending in the direction x and in parallel with each other are supported under floating conditions by way of anchor portions a11-a16 and a21-a26 on a substrate 100 comprising silicon and a first driving frame 45 and a second driving frame 25 arranged in the direction x are supported in a state where spring beams 41-44/21-24 having high distortion in the direction x are supported under floating conditions between the connection beams bbl and bb2.

A first vibrator 51 is supported under a floating condition by spring beams 47-50 extending in the direction x and having high distortion in the direction y and contiguous with the first driving beam 45 inside the first driving frame 45, while a second vibrator 31 is supported under a floating condition by spring beams 27-30 also extending in the direction x and having high distortion in the direction y and in contiguous with the second driving frame 25 inside the second driving frame 25.

Further, there are also provided exciting electrodes 15, 16/35, 36 for driving at tuning fork resonance the first driving frame 45 and the second driving frame 25 in the direction x, first displacement detection electrodes 13 and 14 for detecting y vibrations undergoing the Coriolis force when an angular velocity around the axis Z of the first vibrator 51 exerts on the sensor SEN. and second displacement detection electrodes 33 and 34 for detecting the y vibrations of the second vibrator 31.

In the construction described above, the structure of the movable portion 8a of the invention is applicable to the first and the second vibrators 51 and 31 while the structure of the fixed portions 8b and 8c are applicable to the first and the second displacement detection electrodes 13 and 14/33 and 34, so that the size of the first and the second displacement detection electrodes 13 and 14, and 33 and 34 as the fixed electrode can be reduced and the number of the fixed electrodes in a unit area can be increased to reduce the size of the sensor. In addition, as the number of the displacement detection electrodes is increased, the detection output can be increased by so much to improve the S/N ratio.

According to the invention, since the nitride film is formed between the oxide film and the circuit connection portion, even if the poly-Si is overetched in the case of separating the structural body near the circuit connection portion, the intruding etching solution does not easily reach the oxide film as usual and it can be reliably protected by the nitride film. Accordingly, the sacrificial layer can be protected reliably also upon releasing against etching by the nitride film formed between the oxide film and the wiring connection portion.

In this case, since it is possible to suppress leakage current between the n-layer wiring and p-layer of the substrate by the nitride film, it is possible to improve the yield or the S/N ratio and prevent degradation of the performance of the sensor. Further, when such a construction is applied, for example, to an acceleration sensor or an angular velocity sensor, the size of the anchor portion or the fixed electrode connected electrically to the circuit disposed on the substrate and the number of electrodes can be increased in the unit area to reduce the size of the sensor.

What is claimed is:

1. A micro-machined surface structure comprising a substrate,
a wiring comprising an n-layer or a p-layer formed by diffusion after ion implantation of impurities onto the substrate,
an oxide film for protecting the wiring,
a nitride film formed on the oxide film,
a circuit connection portion electrically connected with the circuit and
a structural body comprising polysilicon formed on the wiring connection portion and on the nitride film, in which the nitride film is formed between the oxide film and the circuit connection portion on the substrate.
